(19) United States
(12) Patent Application Publication
(10) Pub. No.: US 2018/0164241 A1
(43) Pub. Date: Jun. 14, 2018

(54) MICRO-ELECTROMECHANICAL DEVICE, SYSTEM AND METHOD FOR ENERGY HARVESTING AND SENSING

(71) Applicant: Dan Haronian, Efrat (IL)

(72) Inventor: Dan Haronian, Efrat (IL)

(21) Appl. No.: 15/567,632

(22) PCT Filed: Apr. 11, 2016
(86) PCT No.: PCT/IB2016/052040

§ 371 Date: Oct. 19, 2017

Related U.S. Application Data
(60) Provisional application No. 62/230,622, filed on Jun. 11, 2015.

(51) Int. Cl. G01N 27/26; G01N 31/22; H01L 41/113; H02N 2/18; B81B 3/00

(52) U.S. Cl. CPC G01N 27/26; G01N 31/22; B81B 2201/03; H02N 2/18; B81B 3/0064; H01L 41/1136

(57) ABSTRACT

The present invention discloses, inter alia, a micro-electromechanical device (MEMD) for sensing and for harvesting electrical energy responsive to being subjected to mechanical forces, comprising at least one first conductive element fixedly mounted on a first support, wherein the at least one first conductive element is chargeable with electrons; and at least one second conductive element inertia-mounted on a second support such that the first and second supports are electrically isolated from each other.

### CROSS-REFERENCE TO RELATED APPLICATIONS

This application claims priority from U.S. Provisional Patent Application No. 62/230,622 filed on Jun. 11, 2015, titled “Solid State Energy Harvesting Technology” and which is expressly incorporated herein by reference in its entirety.

### TECHNICAL FIELD

The present disclosure relates to micro-electromechanical systems, devices and methods for harvesting electrical energy from mechanical movements as well as for use as chemical and displacement sensors.

### BACKGROUND

Micro-electromechanical devices and systems utilize piezoelectric, electromagnetic or electrostatic converters for converting mechanical movement into electrical energy.

As shown schematically in FIGS. 1A and 1B, a known electrostatic converter 100 has a variable capacitor structure comprising a first and a second capacitor plate 102 and 104 separated by a dielectric 106 (e.g., air) and which are conductively coupled with each other over a conductor 108 having a resistivity or load 155 having an impedance Z. An electret layer 110 is formed on, or constitutes either first capacitor plate 102 or second capacitor plate 104 such as to face the other plate. The electret can be made of SiO₂ and is charged with electrons, for example, by using corona. Further, first and/or second capacitor plates 102 and 104 are mounted to allow alternatingly retracting and approaching movements which, in turn, induces alternating (AC) electric current in conductor 108. Relative retracting and approaching movements of first and second capacitors plates 102 and 104 are schematically illustrated by arrows g1 and g2. For example, first capacitor plate 102 may be moveably mounted (e.g., suspended) to allow its displacement responsive to mechanical vibrations in approaching and retracting directions g1 and g2 relative to second capacitor plate 104 which may be fixed in space. Another possibility is a device configuration in which the gap between the electrodes remains substantially constant yet which oscillate sideways so that the amount of electrode overlap changes periodically. The induced AC may be rectified by rectifier circuitry to generate a direct current (DC), e.g., for charging batteries or powering an electrical device.

If a distance between first and second plates 102 and 104 due to relative displacement in direction G1 is large enough, the charge on the capacitors is redistributed and the electric current flows as schematically illustrated in FIG. 1A by arrow i1. Conversely, if a distance between first and second plates 102 and 104 decreases due to relative approaching displacement in direction D2, then the electric current flows as schematically illustrated in FIG. 1B by arrow i2.

Electrostatic converters that employ electrets are disclosed exemplarily by T. Tsutsumino, Y. Suzuki, N. Kasagi, K. Kashiwagi, Y. Morizawa in “Efficiency Evaluation of Micro Seismic Electret Power Generator”, Proceedings of the 23rd Sensor Symposium 2006, Takamatsu, pp. 521-524; by Ma Wei, Zhu Ruiqing, Rufer Libor, Zohar Yitshak, Wong Man in “An integrated floating-electrode electric microgenerator”, Journal of microelectromechanical systems, v. 16, (1), 2007, February, p. 29-37; and in U.S. Pat. No. 8,796,902 to TATSUAKIRA et al. titled “Electrostatic Induction Power Generator”.

The lifetime of a known electrostatic converter such as converter 100 depends, inter alia, on the charge stability implanted inside the electret.

The description above is presented as a general overview of related art in this field and should not be construed as an admission that any of the information it contains constitutes prior art against the present patent application.

### SUMMARY

Aspects of embodiments relate to a micro-electromechanical device (MEMD) for sensing and for harvesting electrical energy responsive to being subjected to mechanical forces, comprising: at least one first conductive element fixedly mounted on a first support, wherein the at least one first conductive element is chargeable with electrons; and at least one second conductive element which is inertia-mounted on a second support such that the first and second supports are electrically isolated from each other.

Optionally, the MEMD comprises a floating gate charging device (FGCD) having a tunnel oxide, the floating gate charging device used for charging the at least one first fixedly mounted conductive element selectively and controllably by tunneling electrons through the tunnel oxide into the at least one first fixedly mounted conductive element.

Optionally, the FGCD further comprises a source and drain for tunneling hot electrons to a floating gate of the FGCD responsive to applying a voltage between the source and the drain.

Optionally, the FGCD has a charging polarity and a discharging polarity, wherein the discharging polarity is used to drain the electrons out of the at least one first fixedly mounted conductive element.

Optionally, the MEMD further comprises an electronic circuit operably coupled with the at least one inertia-mounted second inertia-mounted conductive element for reading out charge displacement in the at least one second inertia-mounted conductive element resulting from relative movement between the at least one first fixedly mounted conductive element and the at least one second inertia-mounted conductive element.

Optionally, the MEMD comprises a plurality of FGCDs such that each FGCD charges one or more first fixedly mounted conductive elements.

Optionally, the MEMD comprises a plurality of first fixedly mounted conductive elements that are electrically isolated from each other.

Optionally, the MEMD comprises a plurality of first fixedly mounted conductive elements electrically conductively coupled with each other.

Optionally, the MEMD comprises a plurality of second conductive inertia-mounted elements arranged to form a comb-like structure.

Optionally, the induced electrons displacement is rectified for the charging of a battery or the powering of an electrical device.

Optionally, the induced electrons displacement is measured for obtaining a value indicative of a displacement of the MEMD.

Optionally, the at least one first fixedly mounted conductive element is highly doped with Donors atoms to form N type silicon.

Optionally, the at least one first fixedly mounted conductive element is highly doped with Acceptors atoms to form P type silicon such that the charging electrons recombine with holes such that the first fixedly mounted conductive element is charged by negatively charged Acceptor ions.

Aspects of embodiments may also relate to a chemical sensor comprising an MEMD, wherein a negatively charged first fixedly mounted conductive member is used for sensing the presence of positively charged molecules or ions by redistributing the electrons in the second conductive inertia-mounted element upon adhering of such molecules or ions to the at least one first fixedly mounted conductive element.

Optionally, the at least one first fixedly mounted conductive element comprises a chemically modified surface to attract a specific type of molecules and/or ions, such that electrons are redistributed in the second conductive inertia-mounted element upon adhering of such molecules or ions to the first fixedly mounted conductive element.

Optionally, a chemical sensor comprises an FGCD and at least one first conductive element having a surface, wherein the at least one first conductive element is chargeable through the FGCD to create a potential difference between a charging gate of the FGCD and a reference potential and such that molecules and/or ions can adhere to the surface, wherein the adhering causes the electrons to redistribute in the at least one first conductive element, modifying the potential difference between a charging gate of the FGCD and the reference potential.

Optionally, a chemical sensor comprises an FGCD and at least one first conductive element having a surface that is chemically modified to attract specific type of molecules and/or ions, wherein the at least one first conductive element is chargeable through the FGCD to create a potential difference between a charging gate of the FGCD and a reference potential and such that when said specific type of molecules and/or ions adhere to the surface, the electrons in the at least one first conductive element redistribute and modify the potential difference between a charging gate of the FGCD and the reference potential.

Aspects of embodiments may also relate to a system which comprises a plurality of chemical sensors. Optionally, a conductive element of the plurality of chemical sensors is modified in a manner to attract a first type of molecules and/or ions; and wherein another conductive element of plurality of chemical sensors is modified in another manner to attract another type of molecules and/or ions.

Aspects of embodiments may relate to a method of fabricating the MEMD and/or the chemical sensor such that the at least one first fixedly mounted conductive element, the at least one second inertia-mounted conductive element and the FGCD are fabricated on a single wafer such that first fixedly mounted conductive element, the at least one second conductive inertia-mounted element and the FGCD are electrically isolated from each other while the floating gate of FGCD is electrically coupled with the first fixedly mounted conductive element.

Optionally, the method comprises providing an electrical isolating barrier for isolating the FGCD from the at least one first conductive fixedly mounted element.

Optionally, the at least one first fixedly mounted conductive element and the at least one second inertia-mounted conductive element are fabricated on one wafer and the FGCD is fabricated on a second wafer such that when the two wafers are bonded to each other an electrical connection is formed between the floating gate of the FGCD and the at least one first conductive fixedly mounted element.

Optionally, the at least one first fixedly mounted conductive element and the at least one second inertia mounted conductive elements are fabricated from Single Crystal Silicon.

Aspects of embodiments may also relate to a method for charging the MEMD. Optionally, the charging or discharging includes a plurality of charging or discharging cycles.

Optionally, each charging or discharging cycle may take less than one second.

This summary is provided to introduce, in a simplified form, a selection of concepts that are further described below in the Detailed Description. This summary is not intended to identify key features or essential features of the claimed subject matter, nor is it intended to be used to limit the scope of the claimed subject matter.

### BRIEF DESCRIPTION OF THE FIGURES

The figures illustrate generally, by way of example but not by way of limitation, various embodiments discussed in the present disclosure.

For simplicity and clarity of illustration, elements shown in the figures have not necessarily been drawn to scale. For example, the dimensions of some of the elements may be exaggerated relative to other elements. Furthermore, reference numerals may be repeated among the figures to indicate corresponding or analogous elements. The figures are listed below.

FIG. 1A is a schematic circuit diagram illustration of a MEMD showing retracting conductive elements, as known in the art;

FIG. 1B is a schematic circuit diagram illustration of the MEMD showing approaching conductive element, as known in the art;

FIG. 2A is a schematic perspective view of a MEMD, according to an embodiment;

FIG. 2B is a schematic top plan view illustration of the MEMD of FIG. 2A;

FIG. 3A is a schematic perspective view of an MEMD, according to another embodiment;

FIG. 3B is a schematic top plan view illustration of the MEMD of FIG. 3A;

FIG. 3C is a schematic top plan view illustration of an MEMD, according to an alternative embodiment;

FIG. 3D is a schematic perspective view of an MEMD, according to a yet other embodiment;

FIG. 3E is a schematic perspective view of an MEMD, according to a yet alternative embodiment;

FIG. 4A is a schematic perspective side view illustration of a charging arrangement, according to an embodiment;

FIG. 4B is a schematic perspective front view illustration of a charging arrangement, according to another embodiment;

FIG. 4C is a schematic top plan view illustration of the charging arrangement of FIG. 4B;

FIG. 5A is a schematic side view illustration of a charging arrangement and the electron tunneling path, according to an embodiment;

FIG. 5B-1 is a schematic side view illustration of a charging arrangement showing a first charge distribution stage;

FIG. 5B-2 is a schematic side view illustration of a charging arrangement showing a later, second charge distribution stage;

FIG. 6A is a schematic top plan view illustration of a charging arrangement, according a yet other embodiment;

FIG. 6B is a schematic top plan view illustration of a charging arrangement, shown one floating gate charging device charging a plurality of first charged element according to other embodiment;

FIG. 7 is a sequence diagram of the behavior of charge carriers in conductive element, according to an embodiment;

FIG. 8A is a schematic top plan view illustration of an MEMD, according to a further alternative embodiment;

FIG. 8B is a circuit diagram representing the functional electronic elements of the MEMD of FIG. 8A;

FIG. 9A is a schematic top plan view illustration of a combination MEMD, according to an embodiment;

FIG. 9B is a circuit diagram representing the functional electronic elements of the combination MEMD of FIG. 9A;

FIG. 10A is a schematic top plan view illustration of a yet another alternative MEMD, according to an embodiment;

FIG. 10B is a circuit diagram representing the functional electronic elements of the MEMD of FIG. 10A;

FIG. 11A is a schematic top view illustration of a sensing MEMD in an inactive mode, according to an embodiment;

FIG. 11B is a schematic top view illustration of the sensing MEMD in an active mode; and

FIG. 12A-12C show schematic side view illustrations of a charging arrangement at various sensing stages of the sensing MEMD of FIGS. 11A-11B.

FIG. 13 describes a displacement sensor, according to an embodiment;

FIG. 14 describes one stage in a method for manufacturing a charging arrangement, according to an embodiment;

FIG. 15 describes another stage in a method for manufacturing a charging arrangement, according to an embodiment;

FIG. 16 describes yet another stage in a method for manufacturing a charging arrangement, according to an embodiment;

FIG. 17 describes yet another stage in a method for manufacturing a charging arrangement, according to an embodiment;

FIG. 18 describes a stage in a manufacturing process for obtaining a FGCD that is integrated with a first conductive element, according to an embodiment;

FIG. 19 describes another stage in a manufacturing process for obtaining a FGCD that is integrated with a first conductive element, according to an embodiment;

FIG. 20 describes yet another stage in a manufacturing process for obtaining a FGCD that is integrated with a first conductive element, according to an embodiment;

FIG. 21 describes another example of a fabrication process of a MEMD, according to an embodiment.

### DETAILED DESCRIPTION

The following description of Micro-Electro-Mechanical Devices (MEMD), systems and methods for energy harvesting and/or sensing is given with reference to particular examples, with the understanding that such devices, systems and methods are not limited to these examples.

The expression “energy harvesting” as used herein, as well as grammatical variations thereof, refers to the conversion of mechanical motion into electric energy. Such mechanical motion may the result of acceleration and/or vibration on an MEMD according to embodiments. Accordingly, an MEMD according to an embodiment may function as a displacement sensor. Vibrations may be periodic or random or result from forces such as Coriolis force in MEMD gyroscopes. In some embodiments, an MEMD may be employed for energy harvesting. Sensed mechanical motion may be desirable or undesirable (“wasting energy”). Sources of undesirable vibration include, for example, vibrational motions of engines, friction, movement of a tire on a road, walking, mammalian organ and vascular movement, etc.

A micro-electromechanical device (MEMD) includes according to some embodiments one or more first electrically conductive element that are electrically isolated from their surroundings and are selectively electrically chargeable in a controlled manner, and one or more second electrically conductive elements that are electrically isolated from the first member(s). Furthermore, the first conductive elements may also be electrically isolated from one another. The first conductive element can be selectively charged independent of the amount of overlap and/or proximity between the first conductive element and the second inertia-mounted elements.

Merely to simplify the discussion that follows, without it being construed as limiting, the first and second conductive element(s) are each herein referred to in the plural, i.e., as “conductive elements”.

The first conductive elements may be made of any suitable solid state material including, for example, silicon. The first conductive element(s) may be selectively electrically chargeable by employing for example a floating gate charging device (FGCD) that may charge the first conductive element by tunnelling electrons through a thin layer of oxide. In some embodiments, corona charging and/or electron-beam charging techniques may be employed.

The first and/or second conductive elements are oscillatingly mounted to allow them to alternatingly approach and move away from each other when the MEMD is subjected to vibration forces of sufficiently high magnitude. Responsive to the conductive elements movement relative to each other, an alternating current is induced in the MEMD. In one embodiment, either the first or the second conductive elements are coupled with, or constitute an inertia-mounted conductive element. The expression “inertia-mounted” on a support means a conductive element which is mounted such as to be less responsive to a change in external forces compared to being “fixedly mounted” on the support. Hence, when one conductive element is inertia-mounted and another conductive element is “fixedly-mounted” on the same support, and the support is subjected to mechanical forces of sufficient magnitude, relative movement occurs between the inertia-mounted and fixedly-mounted conductive elements. For simplicity, these elements are sometimes referred to herein as “fixed elements” and “inertia elements”.

According to some embodiments, the first conductive elements may be part of a charging arrangement, as outlined and exemplified in more detail herein below. The first conductive elements are isolated from the second conductive elements and from the substrate. The second conductive elements may be connected to an electrical circuit so that charge movement therein is induced upon relative movement between the first and second conductive elements. In some embodiments, a floating gate charging device may be employed to charge an electret. In another embodiment, the MEMD may be operable while being electret-free. Moreover, in some embodiments, the MEMD may be configured and operative so that first conductive elements are selectively rechargeable and/or drainable of their electric charge. According to some embodiments, the first conductive elements may be charged after completion of MEMD packaging and/or close to the use of the MEMD, for example, in less than 1 second or in less than 0.5 seconds. Standard fabrication technologies can be used to manufacture MEMD(s) disclosed herein while improving device usability and its compatibility with state of the art VLSI.

In an embodiment, the first and second conductive elements may, for example, be manufactured using a Silicon-on-Insulator (SOI) wafer (e.g., a silicon carry wafer coated by thin layer of oxide and on top of it bonded silicon layer), or a Silicon on Glass (SOG) wafer.

The expression “electrically isolated” with respect to the “first conductive element(s)” as used herein may refer to a state in which the first conductive element(s), under normal operating conditions, are electrically isolated from the wafer substrate, e.g., through an oxide layer and from each other by space. Such normal conditions exclude the application of electron leakage from the first conductive element to the substrate or to the other conductive element from which the first conductive element is isolated, for example, by air, inert gas, or vacuum. The separation distance may be in the order of microns. It is noted that a conductive element may be considered to be electrically isolated even when it can be charged using a FGCD using a proper tunneling setup or using corona charging.

The first and the second conductive elements are configured and arranged relative to each other such to enable relative motion between the conductive elements, e.g., responsive to subjecting the MEMD to vibrational motion. The first and second conductive elements alternatingly move in an approaching and retracting movement relative to each other such to induce an electrical current in the associated circuit. Otherwise stated, the gap between the first and second conductive elements may oscillatingly decrease and increase. In another example, the first conductive elements and the second conductive elements may be arranged to enable them, in operation, to alternatingly move sideways relative to each other such that the overlapping area changes instead of the gap between the two conductive elements.

When the MEMD is subjected to forces which cause the conductive elements to alternatingly move relative to each other to induce electric current, the MEMD is considered to be “in operation” or “in an operative state”. Conversely, when the MEMD is not subjected to operative forces the MEMD is considered to be at “rest”.

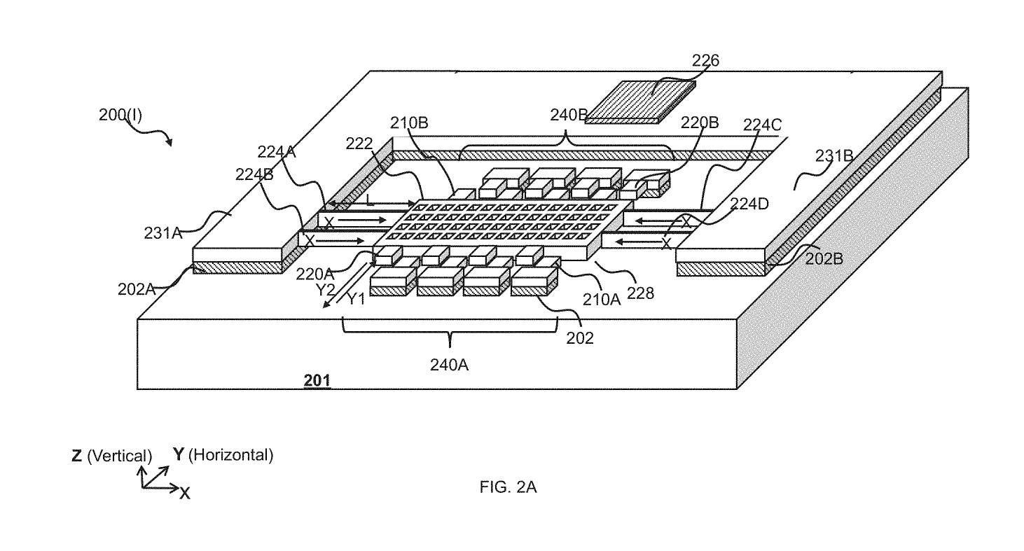

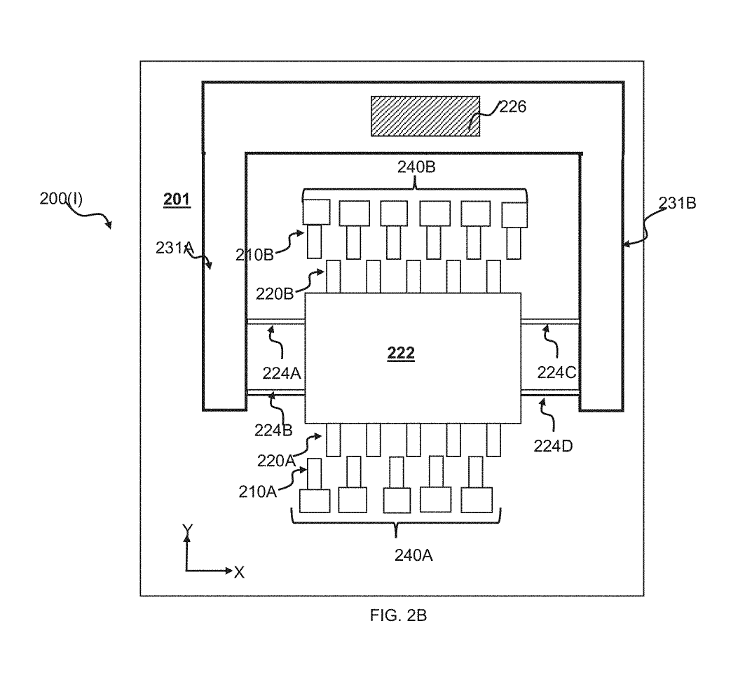

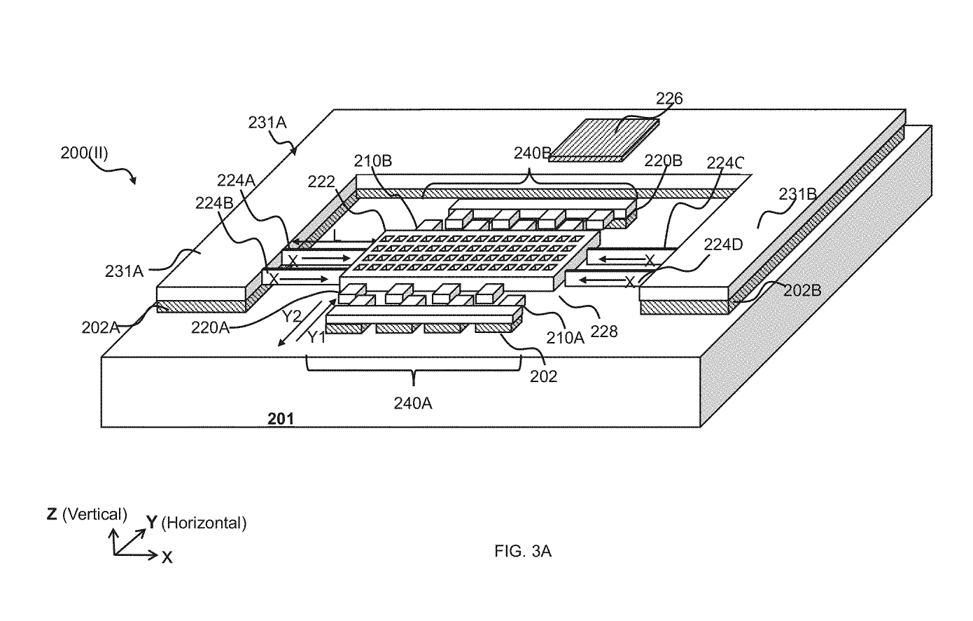

Reference is made to FIG. 2A, which schematically illustrates a perspective view of a MEMD 200(I); and to FIG. 2B, which schematically illustrates a top planar view illustration of MEMD 200(I) according to the embodiment shown in FIG. 2A. In MEMD 200(I) shown in FIGS. 2A and 2B, each one of conductive elements 210A are electrically isolated from each other.

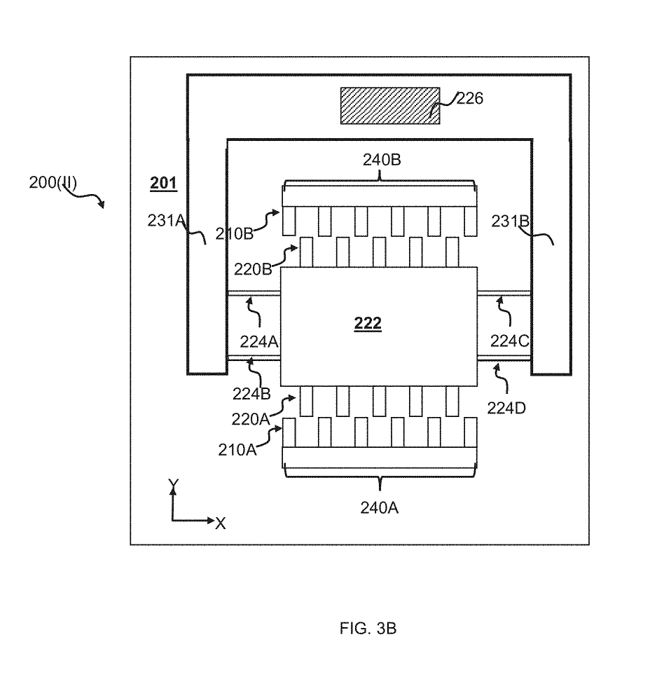

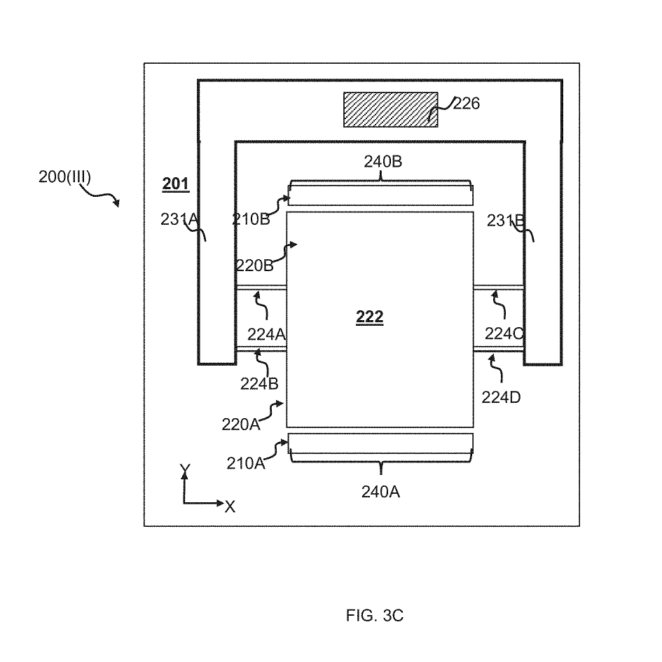

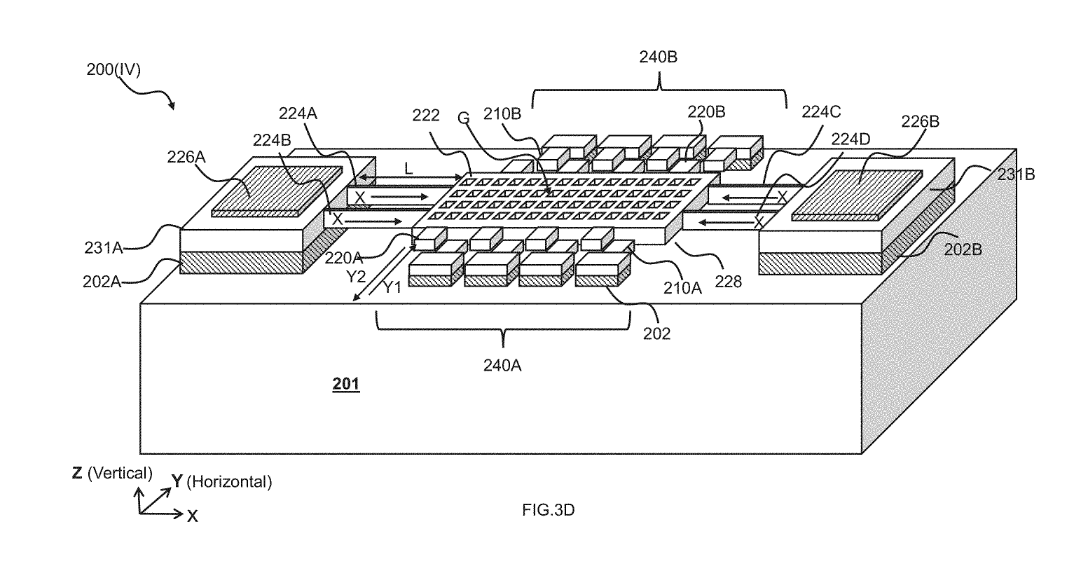

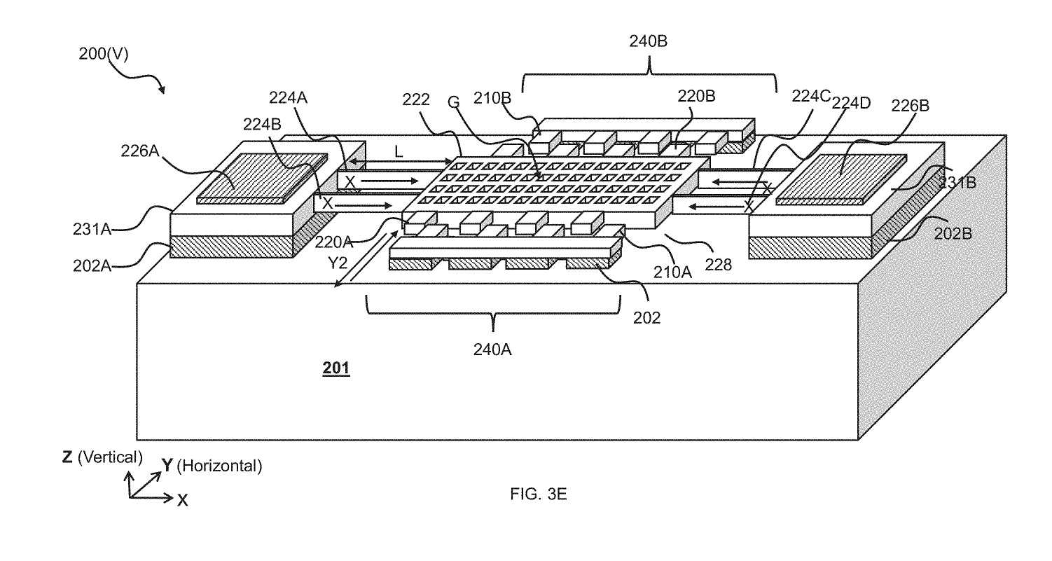

In MEMD 200(I), each conductive element 210 has to be charged individually. Moreover, reference is made to FIG. 3A, which schematically illustrates a perspective of a MEMD 200(II); and to FIG. 3B, which schematically illustrates a top planar view of MEMD 200(II), according to the embodiment of FIG. 3A. In MEMD 200(II), shown in FIGS. 3A and 3B, conductive elements 210A are conductively coupled with each other. Accordingly, in MEMD 200(II), conductive elements 210 can be charged from any point on the conductive element as the charging electrons diffuse across the element. In addition, the electrons may distance themselves from each other and end up occupying the periphery of the volume of the material of the first conductive element, i.e., close to the elements' surfaces.

As shown schematically in FIGS. 2A to 3C, in an embodiment, with respective reference to a first side 240A and a second side 240B of MEMD 200, first fixedly mounted conductive elements 210A and 210B and oscillating conductive elements 220A and 220B may be arranged in a laterally interlacing manner to form a comb-like structure. For instance, in one embodiment, as shown in FIG. 3A when proceeding in the X-direction along first side 240A, a first conductive element 210 is followed by a second conductive element 220, which is again followed by another first conductive element 210, etc., or vice versa.

In another instance exemplified by a MEMD 200(III), a single first conductive element 210 and a single second conductive element 220 may have straight surfaces facing each other. As shown in FIGS. 2A-3C, support members 231A and 231B are legs of a U-shaped support structure.

Additionally referring to FIGS. 3D and 3E, a MEMD 200(IV) and a MEMD 200(V) may have individual support members 231A and 231B.

To simplify the discussion that follows, MEMDs 200(I)-200(V) are herein collectively referred to as MEMD 200, unless the description refers to the operable differences resulting from the different coupling configurations of the conductive element.

First conductive elements 210 can be electrically charged, e.g., in a controlled manner using a FGCD. Second conductive elements 220 are suspended and connected to an electrical circuit (not shown). To simplify the discussion that follows, without being construed limiting, the following description refers to a configuration in which the first conductive elements that can be electrically charged using exemplarily a FGCD. Accordingly, in some embodiments, the charged conductive elements may be fixedly mounted, while charge is induced in the circuit through the other, inertia-mounted (second) conductive elements. The term “selectively chargeable” refers to controlled and selective electric charging of material using a FGCD).

First conductive and charged elements 210 may be fixedly arranged in an isolated manner on a carrier wafer layer 201 to operably cooperate with second conductive elements 220. The expressions “operably cooperate” or “operably mounted” as used herein with respect to “conductive elements”, as well as grammatical variations thereof, may refer to an arrangement in which the oscillating movement of one conductive element relative to a second conductive element, can induce electric current in an electrical circuit which is connected to the second conductive element, when the first conductive element is charged.

In an embodiment, first and second conductive element may be made of a Single Crystal Silicon (SCS) on insulator carry wafer. Insulator carry wafer may for example be made of oxide on silicon wafer, glass wafer and/or any other suitable material.

It should be noted that the number of first and second conductive elements 210 and 220 shown in the accompanying figures is for exemplary purposes only and should by no means to be construed as limiting.

In an embodiment, first and second conductive elements 210 and 220 may lie in the same plane. First conductive elements 210 may be rigidly mounted onto electrically isolating island layers 202 (e.g., oxide layers) in a cantilevered manner so that a portion of each one of first conductive elements 210 is extending from a proximal coupling area of the respective isolating island layers 202. The extension part may be suspended in air in order to reduce the overall supporting oxide. The same is true for conductive element 210, in general, as shown in FIGS. 3A and 3E. Such a reduction in the supporting oxide area reduces the capacitance to the substrate and reduces the area through which electron may leak (through the oxide) to the substrate. Isolating island layers 202 overlay carrying wafer layer 201 so that first conductive elements 210 are isolated from carrying wafer layer 201, as well as from second conductive elements 220.

First conductive elements 210 may be electrically chargeable without requiring the employment of electrets. In other words, first conductive elements 210 and, hence, MEMD 200 may be electret-free. First conductive elements 210 may be selectively electrically chargeable by employing a FGCD or collectively by using corona charging and/or electron-beam charging techniques. Electrons that may be collected by second conductive members 220 may vanish once the MEMD is connected to an electrical circuit.

In some embodiments, MEMD 200 may be configured and operative so that first conductive elements 210 are rechargeable and/or drainable. According to some embodiments, first conductive elements 210 may be selectively charged after completion of MEMD packaging and, optionally, close to the use of MEMD 200 when employing a FGCD.

In an embodiment, an inertia element 222 that holds the second conductive elements 220 may be oscillatingly coupled with a support 231. Inertia element 222 and conductive elements 220 may together have a center of gravity G. For example, second conductive elements 220 may extend in a cantilevered manner from an inertia element 222 so that a portion of each one of second conductive elements 220 extends from a proximal coupling edge of inertia element 222.

In an embodiment, inertia element 222 may be carried by one or more leaf-type spring elements (also “spring elements”) 224. Spring elements 224 may have a flexible length L allowing inertia element 222 and second conductive elements 220 to oscillate in the Y direction in X-Y plane relative to first charged and conductive elements 210 when MEMD 200 is in operation. The space between carrying wafer layer 201 and inertia element 222 and spring elements 224 may be, for example, air, inert gas or vacuum, depending on the packaging of the MEMD. In some embodiments, second conductive elements 220 may be mounted and configured so that they may oscillate in other planes than in the Y-Z plane relative to first conductive element 210. For example, inertia element 222 may lie in any oscillator position in an X-Y plane that has the same Z-position, and may oscillate relative to first conductive and charged elements 210 rectilinearly in positive and negative directions Y1 and Y2 which may be perpendicular to the longitudinal axes X of spring elements 224. In operation, the spring elements may thus flex in an “S”-fashion.

Other spring configurations than the one described herein may be employed including, for example, a folded spring. Clearly, additional or alternative suspension configurations may be used. For example, in some embodiments, an inertia structure may be suspended from one side only in a cantilever manner.

In an embodiment, one or more spring elements 224 may extend from inertia element 222 to form a bridge 228 between supports 231A and 231B that are respectively arranged on opposing sides of inertia element 222 on island layers 202A and 202B so that the inertia element is suspended by and between supports 231A and 231B to allow the inertia element to oscillate relative to first conductive elements 210. For example, two spring elements 224A-224B may extend from inertia element 222 from one side thereof and terminate in a first island 202A. Two other spring elements 224C-224D may extend from inertial element 222 from the other, opposite side and terminate in a second island 202B. A pad 226 (FIGS. 2A-3C) or pads 226A and 226B (FIGS. 3D and 3E) for making contact between a circuit and second conducive members 220 can be made of metal. In FIGS. 3D and 3E only one pad may be required to be connected to the electrical circuit.

In some embodiments, MEMD 200 may comprise one or more sets of cooperating first and second conductive elements 210 and 220. For example, a first set of cooperating fixedly mounted conductive elements 210A and oscillating elements 220A may be arranged at a first side 240A of MEMD 200 and another set of cooperating fixedly mounted first conductive elements 210B and oscillating second conductive elements 220B may be arranged at another, second side 240B which is opposite the first side. First conductive elements 210A may be, for example, arranged on individually isolating island layers 202 that are arranged along a part of first side 240A on carrying wafer layer 201. Further, second oscillating conductive elements 220B may be, for example, arranged on individually isolating island layers 202 that are arranged along at least a part of first side 240B on carrying wafer layer 201. In some embodiments, even with two different individual supports, only one pad may be employed.

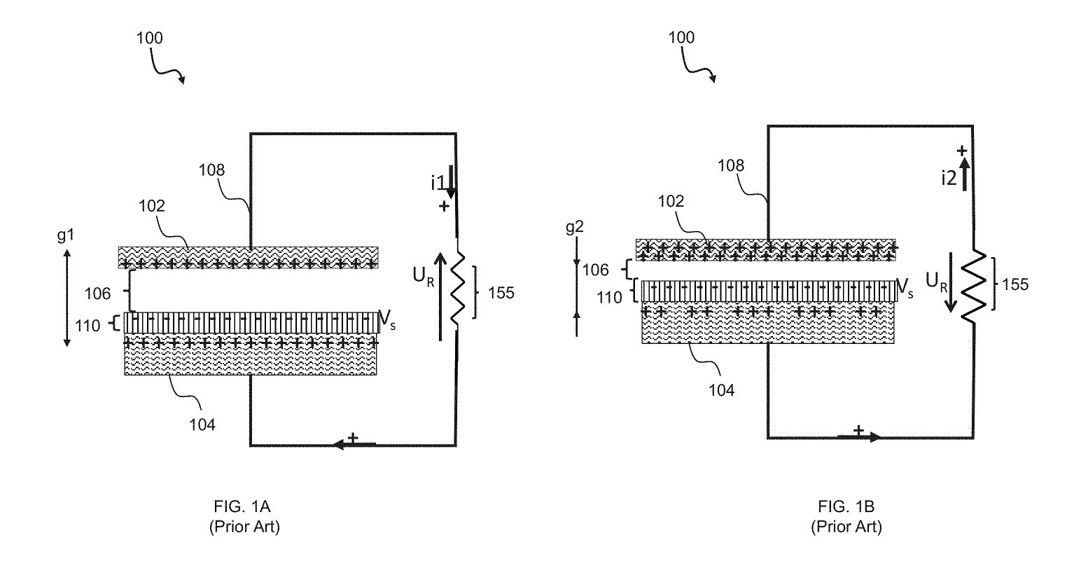

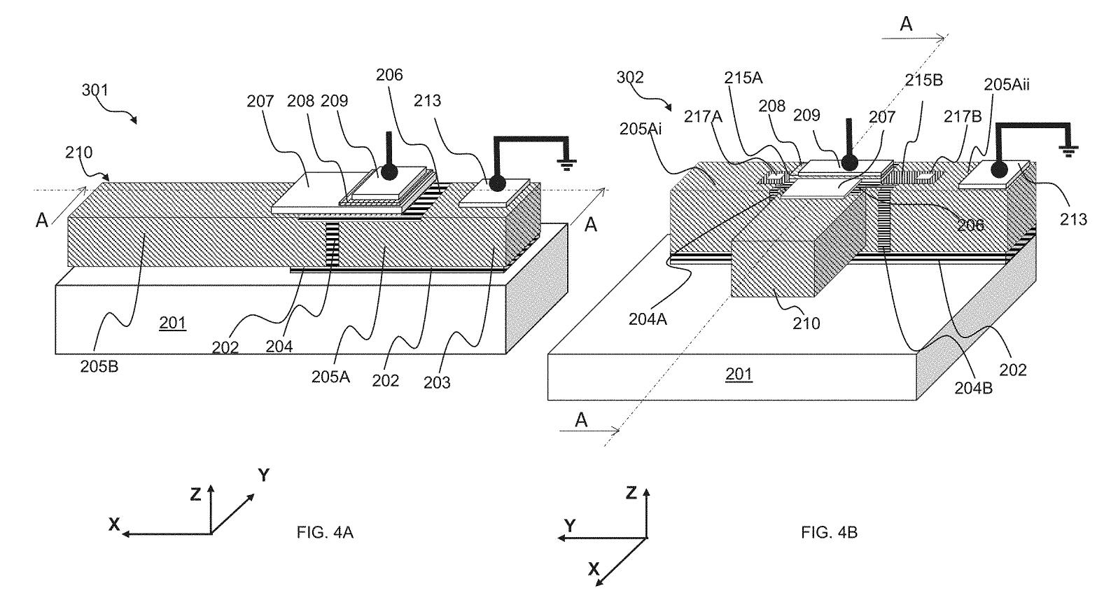

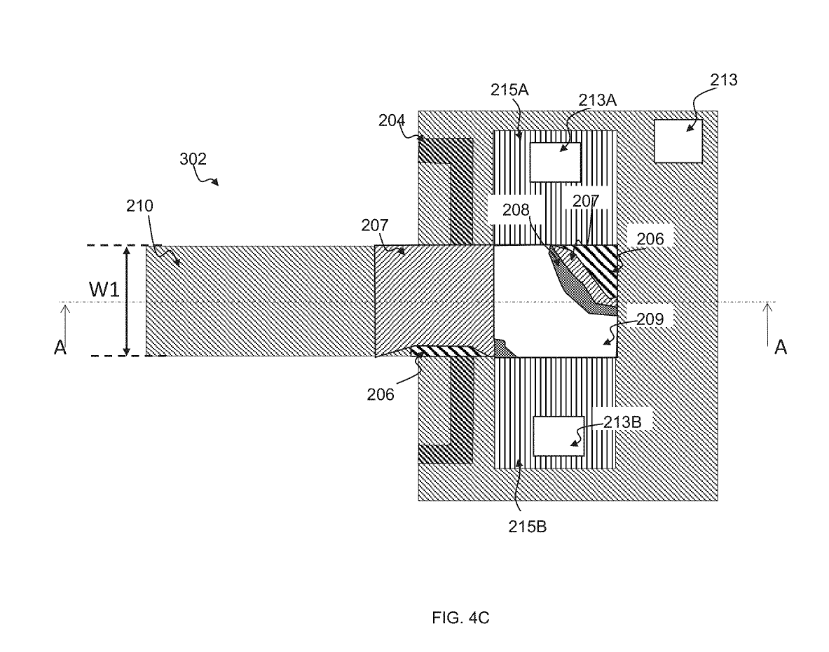

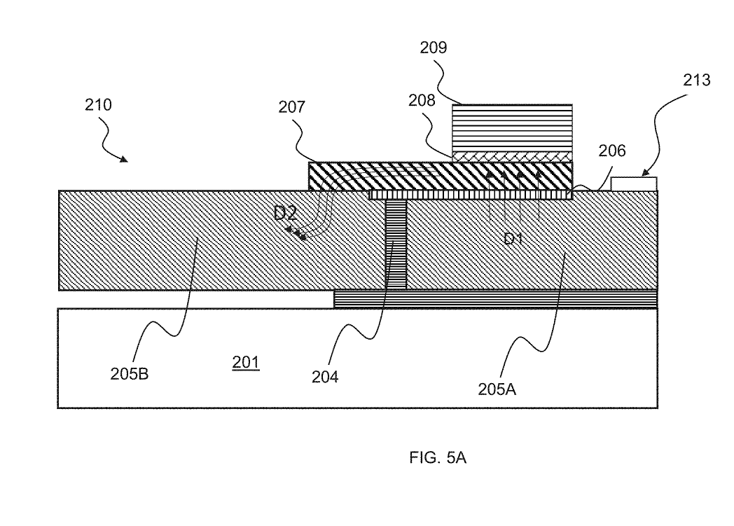

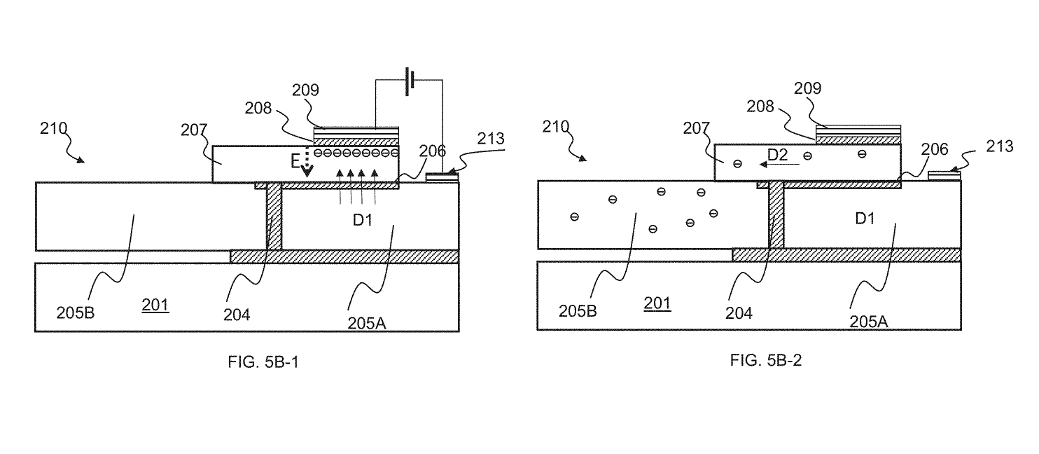

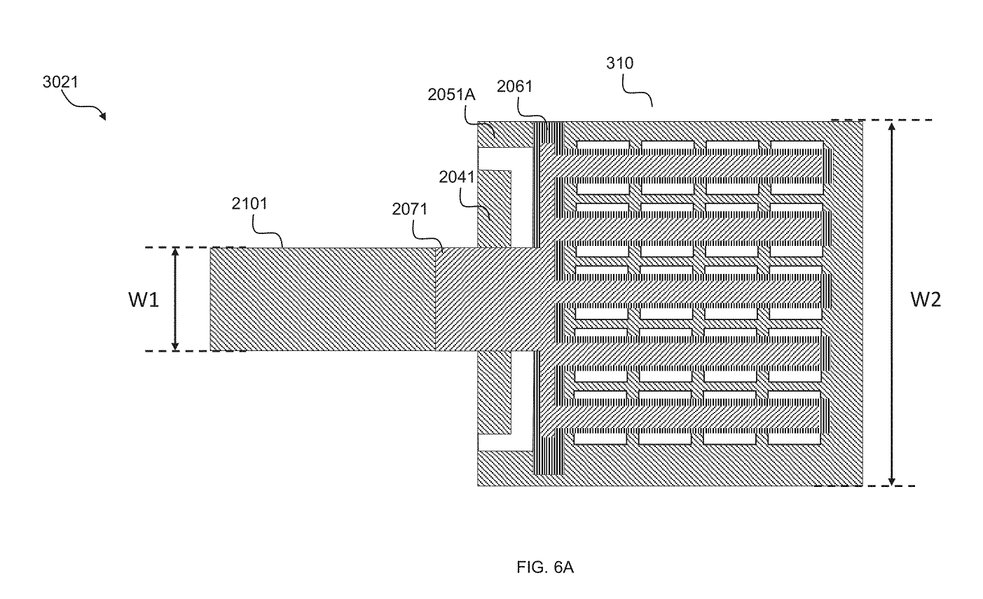

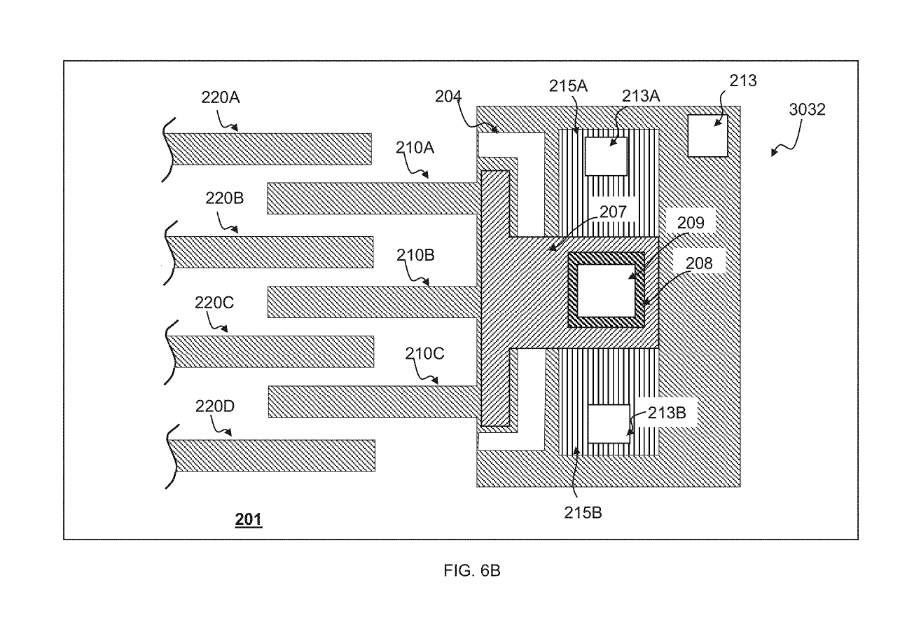

Additional reference is now made to FIG. 4A, which shows a schematic perspective side-view illustration of a first configuration of the FGCD 301 according to some embodiments; to FIG. 4B, which shows a schematic perspective front-view illustration of a second configuration of the FGCD 302, according to some alternative embodiments; and to FIG. 4C which shows a schematic top plan view illustration of a charging arrangement 302. Moreover, reference is also made to FIG. 5A, FIG. 5B-1 and FIG. 5B-2 which shows the cross section A-A indicated in FIGS. 4A-4C, according to some embodiments; and to FIGS. 6A and 6B which shows a schematic plan top view illustration of yet another FGCD charging arrangement, according to an alternative embodiment.

Referring to FIG. 4A, charging arrangement 301 may comprise an island layer 202 on carrying wafer layer 201 and a conductive layer 203 partly connected to carrying wafer layer 201 through isolated layer 202 and partly suspended. Conductive layer 203 may be divided into a proximal conductive portion 205A and a distal conductive portion 205B by an isolating barrier 204 which extends perpendicularly from island layer 202 up to the upper surface of conductive layer 203. The distal conductive portion 205B may constitute conductive element 210 (e.g., a silicon-electrode element), which may herein also be referred to as electrode 210. Some (e.g., the majority) but not all of distal conductive portion 205B may be suspended or cantilevered over the part of carrying wafer layer 201 which is not covered with isolating layer 202. The upper surface of isolating barrier 204 may be in substantially the same plane as the upper surfaces of proximal and distal conductive portions 205A and 205B.

A tunneling oxide layer 206 may overlay a part of proximal conductive portions 205A, extending entirely over the upper surface of isolating barrier 204 and further over a part of distal portion 205B such that some of the distal conductive portion 205B remains exposed. In an embodiment, the oxide beyond isolating barrier 204 (i.e. in a distal direction away from the FGCD structure) may be thicker than the tunnel oxide as no tunneling current flows beyond this point. Such a “thick” oxide may be required to improve isolation and reduce parasitic capacitance. Furthermore, a floating gate layer 207 may overlay tunnel oxide layer 206 and “spill over” the distal edge of tunnel oxide 206 to cover an additional area of the upper surface of distal conductive portion 205B, sufficiently to create a good electrical contact that will allow electrons to flow without much resistance.

On top of floating gate 207, a gate isolating layer 208 and a charging gate layer 209 are disposed. A reference pad 213 may be disposed over the proximal edge of the floating gate arrangement of tunnel layer 206 so that a voltage can be built up between distal gate layer 209 and reference pad 213, allowing the tunneling condition and electrons flow for charging the floating gate 207. It is noted that in this way the first conductive element(s) can be considered to be charged “directly”, since the floating gate of the FGCD is directly coupled to and integrally formed with the first conductive element.

Floating gate layer 207 can for example be made of conductive material such that electrons tunneling into the floating gate will flow along it to conductive portion 205B.

As shown schematically in FIG. 4B, a charging arrangement 302 may include a Source 215A and Drain 215B with electrical pads 217A and 217B respectively. In some embodiments, source 215A and the drain 215B are doped silicon with doping type that is opposite to the substrate type. That is if the substrate is P type, the S and the D are N+ type. The “+” signs indicates that the material is highly doped. Numerals 205Ai and 205Aii indicate the left and right portions of the T-shaped FGCD arrangement. Numerals 204A and 204B indicate the right/left barrier portions of the floating gate arrangement. The shading in the Figures defining the Source and the Drain are for illustrative purpose only. As in the configuration shown in FIG. 4A, charging Gate 209 creates a tunneling path that allows electrons to flow from the substrate to the floating gate. By applying a voltage between the source and the drain, electrons flow along a conductive channel under the tunnel oxide. Some of these electrons, called “hot” electrons because of their kinetic energy, change their direction and tunnel to the floating gate such that the charging effect is enhanced compared to a process where the charging is done only by applying a gate voltage.

As shown schematically in FIG. 4C, a suspended electrode (conductive element) 210 may have a width W1 ranging, for example, from about 1 μm to about 2 μm, or of the order of several microns. Additional reference is made to FIG. 5A, which schematically illustrates the electron propagation path responsive to the application of a tunneling condition as a result of gate voltage. This description is also valid in case of hot electrons, in case of Source and Drain arrangement, and voltage is also applied between the source and the drain.

When a tunneling voltage is applied between gate 209 and the reference pad 213 and between the source and the drain (in case of a configuration that includes source and drain), electrons tunneled from proximal conductive portion 205A via tunneling oxide layer 206 charging floating gate layer 207 (schematically illustrated by arrow D1), and, further by diffusion, to distal conductive portion 205B of conductive element 210 (as schematically illustrated by arrow D2).

Reference is made to FIGS. 5B-1 and 5B-2. Since the field between the charging gate and the substrate is limited to their overlapping area, the electrons may concentrate there as shown schematically in FIG. 5B-1. When the voltage is dropped to zero and the field vanishes, the electrons may diffuse to the floating gate extension and to conductive element 210 as shown in FIG. 5B-2. In this case, the charging arrangement works as a charge pump, where each charging cycle pumps more electrons to charge conductive element 210. The charge pulses may be very short so that the steps shown in FIGS. 5B-1 and 5B-2 may take less than a second.

Upon removal of the tunneling voltage, the tunneling condition stops and no electrons can flow through the tunnel oxide. The electrons are trapped in the floating gate and then distribute throughout this conductive and isolated volume of conductive element 210. It is reasonable to assume that to some extent the electrons will flow away from each other and thus be closer to the envelope of this volume of 205B (element 210). The electron concentration may be similar to that of floating gate memory and is calculated to be in the order of 10⁸-10¹⁹ electrons per cm³.

Charge may be pumped (drained) out of the element by reversing the polarity of the charging gate voltage and by using a similar cycling method

Further reference is now made to FIG. 6A, which illustrates schematically a charging arrangement 3021 comprising a plurality of FGCD, 310, respective “sources” and “drains” of a floating gate extension and layer 2071 that are arranged and operable to enable the selective charging of a conductive element 2101, through floating gate 2071 that extends to contact element 2101 according to some embodiments. In other words, a plurality of floating gates may be employed for charging a conductive element. As shown schematically in FIG. 6A, there is practically no limitation on the width W2 of floating gate extension layer 2071. Width W2 can for example range from 0.5 μm to 100 μm or more. A barrier 2041 isolates a proximal conductive portion 2051A from a conductive element 2101.

Further reference is now made to FIG. 6B, which illustrates schematically a charging arrangement 3032 comprising a plurality of first conductive elements 210A-210C that are charged by one FGCD that includes a source and a drain.

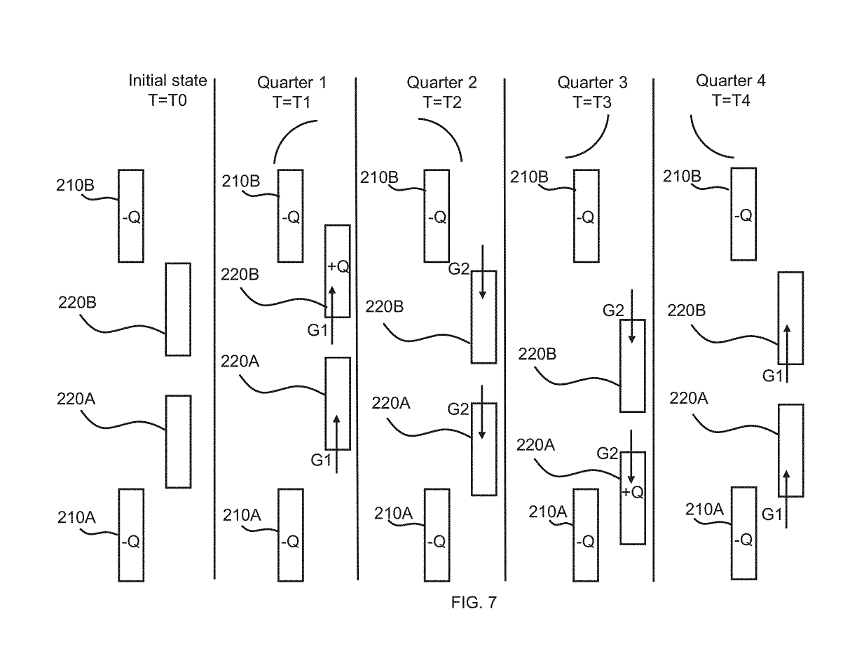

Further reference is made to FIG. 7, which illustrates schematically a sequence diagram of the behavior of charge carriers in conductive elements 210 of a MEMD according to embodiments, at different time stamps during an oscillation period.

At an initial stage t=t0, no external forces are applied on MEMD 200. Responsive to subjecting MEMD 200 to external vibrational forces of sufficient magnitude, first and second oscillatingly mounted (suspended) conductive elements 220A and 220B may jointly move or be displaced upward to the same extent relative to fixedly mounted conductive and charged elements 210A and 210B. The upward movement is in a first direction, schematically illustrated by arrows G1. This relative movement rejects electrons in conductive element 220B. As conductive elements 220B and 220A are connected to an electrical circuit, current may be induced in the circuit. Further, as indicated with respect to t=t2, the vibrational forces may cause inertia-mounted conductive elements 220A and 220B to jointly move downward relative to fixedly mounted conductive elements 210A and 210B in opposite direction to G1, which is schematically illustrated by arrows G2. During the downward displacement, at t=t2 the position of the conductive elements may momentarily be as at t=t0 and from there the two conductive elements move as indicated in arrow G2 such that conductive element 220A is in close proximity to conductive element 210A. When at sufficient proximity electrons are rejected from element 220A which in turn induces current in the electrical circuit. Conductive element 210A and 210B return to the initial position at t=t4 and complete a full vibration cycle.

The fixedly mounted conductive elements 210A and 210B are negatively charged. Moreover, initially, there may be no overlap between suspended (oscillatingly) mounted conductive elements 220B and fixedly mounted conductive elements 210A. Therefore, there is no significant charge induced on suspended conductive elements at the initial state T=TO.

It is noted that overlap between the conductive elements is not necessarily a requirement for current to be induced. In some embodiments, it may suffice that the conductive elements come in sufficient proximity to each another. However, the larger the overlap at sufficient proximity the more electrons are rejected.

It is noted that in some embodiments, as exemplified herein below, a MEMD may be configured so that during an entire oscillation period fixedly and suspended conductive elements may always overlap.

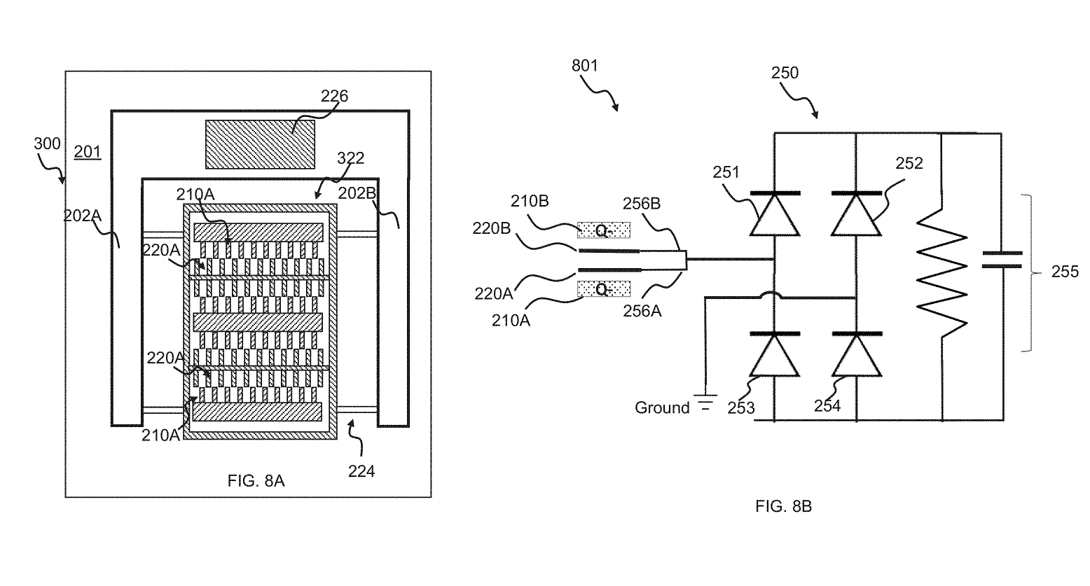

Additional reference is made to FIG. 8A and to FIG. 8B. FIG. 8B, schematically illustrates a circuit diagram 801 representing the functional electronic elements of MEMD 200 device shown in FIGS. 3A, 3B and 8A. Electrodes which are inertia-mounted are designated by reference numerals 220A-220D. Non-inertia (i.e. fixedly) mounted conductive and charged elements are designated by reference numerals 210A-210D. According to some embodiments, conductive elements 210A-210D may be operably coupled with a diode bridge 250 comprising four diodes 251-254 and a load 255 of given impedance Z, comprising, e.g., a resistor and a capacitor coupled in parallel via electric conductive pad 226 such as to generate a DC output over load 255.

For example, responsive to the transition from the initial stage (t=t0) to the first quarter of the periodic movement (t=t1) (cf. FIG. 7) during which inertia mounted elements 220B move upwards and thus closer to second fixed conductive elements 210B, electrons flow in the circuit. Since current is defined as movement of positive charge, this electron flow is equivalent to a (positive) current flowing in the opposite direction, from a reference potential which may be implemented, for example, by ground voltage, through diode 252 and through the load (e.g., resistor and capacitor) from top to bottom. From there, the current flows through diode 253 to pad 256B. Responsive to the transition from Quarter 1 (t=t1) to Quarter 2 (t=t2) during which inertia-mounted conductive elements 220B move back to their initial position, current flows in the opposite direction. That is, from pad 256B through diode 251 and through the load 255 from top to bottom, and from there through diode 254 to the reference potential. Furthermore, responsive to the transition from Quarter 2 (t=t2) to the third quarter (t=t3), the suspended conductive elements move down so that the lower (first) suspended conductive elements 220A move closer to lower (first) fixed conductive elements 210A such that electron flow from pad 256A to the circuit. Once again this is equivalent to positive current flowing in the opposite direction. That is, Reference potential->Diode 252->Load 255 from top to bottom->Diode 253->Pad 265A. Finally, responsive to the transition from Quarter 3 (t=t3) to Quarter 4 (t=t4), the conductive elements move back to their initial state causing current to flow from Pad 265A to the reference potential in the following route: Pad 256A->Diode 251->Load+load 255->Diode 254->Reference. Note that the actual movement is of electrons in the opposite direction, so actually electrons flow from the reference potential to inertia-mounted conductive elements 220A where charge is missing.

As shown in FIG. 8A, oscillating conductive elements 220A may be mounted in a double-sided comb-like manner onto an inertia element 322 having a frame-shaped rim. Compared to MEMD 200 shown in FIGS. 3A and 3B, inertia element comprises two additional pairs of cooperating upper and lower conductive elements. As already outlined herein, the electric circuit diagram shown in FIG. 8B can represent the configuration of MEMD 300 shown in FIG. 8A.

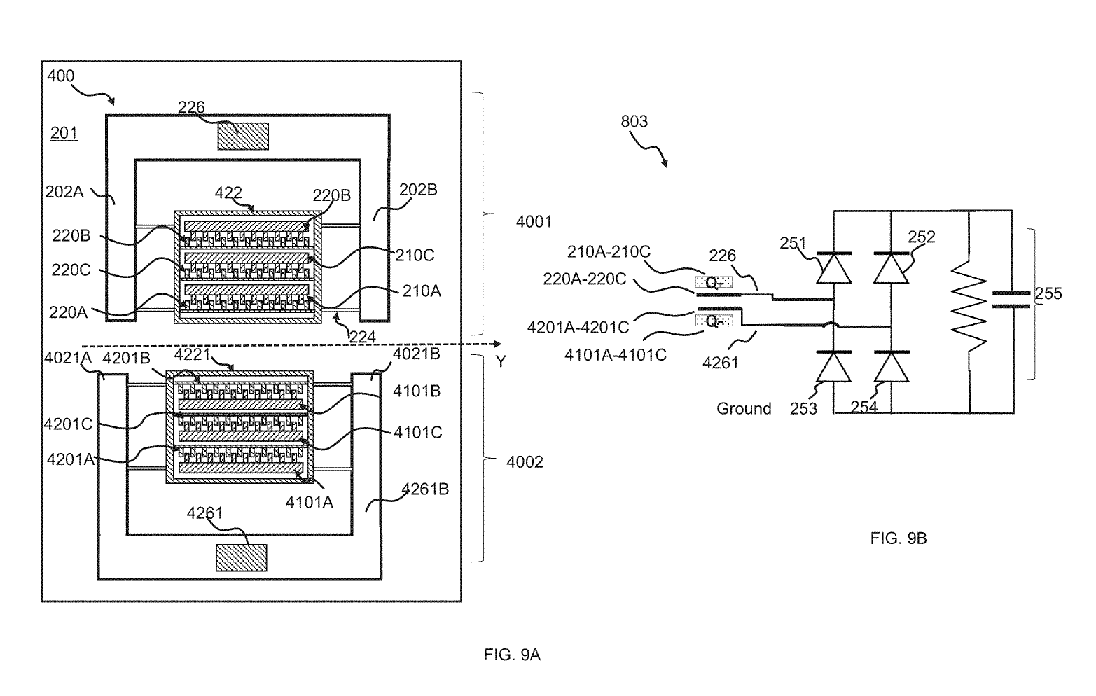

Reference is further made to FIG. 9A, which schematically illustrates a combination MEMD 400 comprising a plurality of MEMDs (e.g., MEMD 4001 and 4002) comprising reverse (mirror-like) oscillatingly mounted conductive elements according to some embodiments; and to FIG. 9B which schematically illustrates a circuit diagram 803 representing the functional electronic elements of MEMD 400 device shown in FIG. 9A. As shown in FIG. 9A, inertia-mounted conductive elements of both first and second MEMDs 4001 and 4002 may be mounted in a single-sided comb-like manner onto respective inertia elements 422 and 4221 which may have a frame-shaped rim. Further, suspended conductive element 220A-220C are mounted to oscillate in relative direction which is reverse or opposite a concurrent oscillation direction of suspended conductive elements 4201A-4201C. In other words, fixedly mounted electrodes 210A-210C of MEMD 4001 are operably mounted in a mirrored manner (with respect to horizontal Axis Y) relative to the fixedly mounted electrodes 4101A-4101C of MEMD 4002. Correspondingly, suspended electrodes 220A-220C of MEMD 4001 are operably mounted in a mirrored manner (with respect to horizontal axis Y) relative to suspended electrodes 4201A-4201C of MEMD 4002. Hence, the relative oscillation direction of the suspended conductive elements of first MEMD 4001 is mirrored with respect to oscillation direction of second MEMD 4002. For example, while suspended conductive elements 220A move away from fixedly mounted elements 210A, suspended conductive elements, 4201A approach relative to fixedly mounted elements 4101A and vice versa.

As shown schematically in FIG. 9A, when at rest, i.e., at an initial stage, fixedly mounted conductive elements 210 and suspended elements 220 may overlap so that charge may be induced in the suspended electrodes. Therefore, when the frames of both MEMD 4001 and 4002 move downwards, the overlapping between the suspended electrodes in upper device MEMD 4001 increases. Conversely, in lower device MEMD 4002 the two sets of electrodes retract, decreasing overlap. Additional reference is made to FIG. 9B, which schematically illustrates a circuit diagram 803 representing the functional electronic elements of MEMD 400 device shown in FIG. 9A. The two devices MEMD 4001 and 4002 are operably connected with each other. There is an initial charge induction on the suspended electrodes and therefore when the frames of the devices move down the gap between electrodes 220 and 210 in MEMD 4001 gets smaller and therefore electrons are rejected from the upper set of suspended electrodes (220A-220C). The downwards movement of the device increases the gap between electrodes 220 and 210 in MEMD 4002 and therefore electrons are attracted to the lower set of suspended electrodes (4201A-4201C). Therefore (positive) current will flow in the circuit in the following path from conductive elements 4201A-4201C to pad 4261 to diode 252 from there to load in up to down direction. Next the current will flow from diode 253 to pad 226 and to conductive elements 220A-220C. In the opposite relative movement, current flows in the opposite direction, from conductive elements 220A-220C to pad 226—to diode 251 and load from top to bottom. From there, the current flows through diode 254 and from there to conductive elements 4210A-4201C through pad 4261.

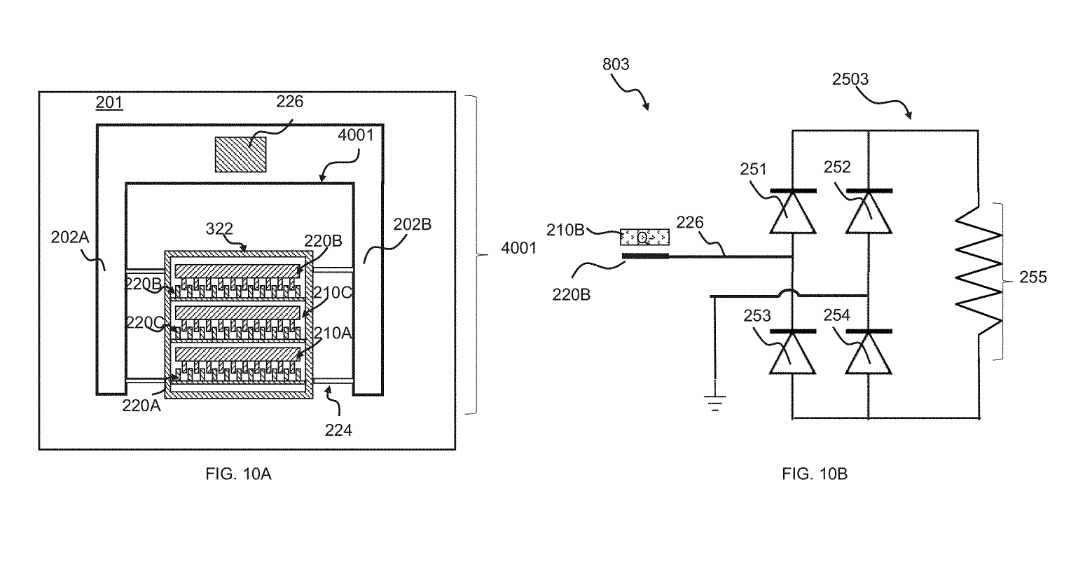

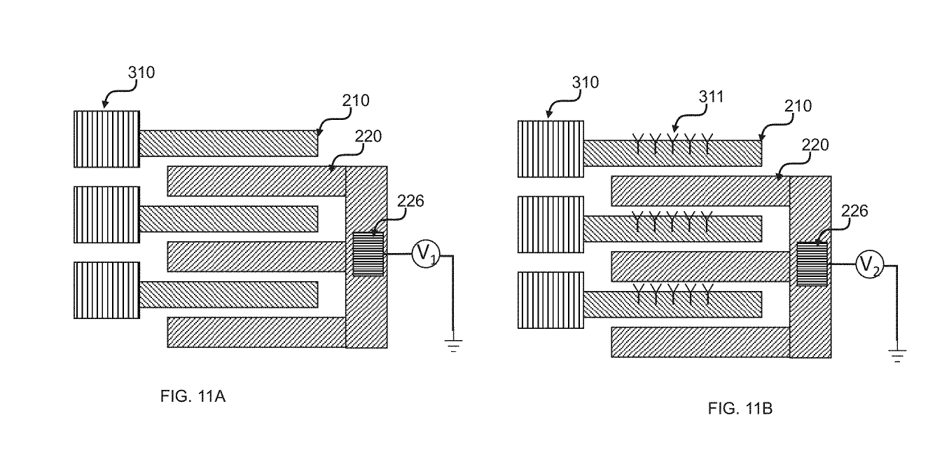

Reference is now made to FIG. 10A, which schematically illustrates MEMD 4001 alone; and to FIG. 10B, which schematically illustrates a circuit diagram 803 representing the functional electronic elements of MEMD 4001 device shown in FIG. 10A. When only one MEMD is used, the other side of the circuit can be connected to the reference potential, as illustrated schematically in FIG. 10B, such that current flows from and to the reference potential.

According to some embodiments, the selectively chargeable conductive elements may be made of P-type or N-type semiconductor material. As well known, the majority mobile charge carriers in N-type semiconductors are electrons and in P-type semiconductors are holes. To keep the semiconductor material electrically neutral, the electrons and holes are balanced by (respectively) positive and negative ions. In the event that P-type semiconductor material is employed, electrons that are tunneled to the conductive elements may recombine with the holes thus leaving the material charged with negatively charged ions. As a consequence, charge is less likely to move and eventually leak out of the isolated conductive element either through the tunnel oxide or through the outer surface of the charged conductive element.

Assuming for example that a conductive element 210 is 2 μm wide, 10 μm deep and 20 μm long. The volume of the conductive element is then 4⁻¹⁰ cm³. Assuming a required charge concentration of 10¹⁸ cm³, the number of electrons required is 48. This means a FGCD with a charging gate 209 area of 250 μm², or for example a charging gate 209 with a size of 15×15 μm per conductive element 210. The charging may take place through one long charging cycle or it may take place through several charging cycles. The area of the charging 209 is inversely proportional to the charging time. That is, the larger the gate area the more electrons can tunnel through the oxide in a given time period and thus the shorter the charging time. For example, with two charging cycles, the area of charging gate 209 drops to about 125 μm², i.e. to a charging gate of about 11×11 μm per conductive element 210. In the calculation above we assume that the volume of the floating gate 207 underneath the charging gate 209 is negligible compared to element 210.

A microelectromechanical system may comprise a plurality of MEMDs. Aspects of embodiments also relate to a method of a charging arrangement of a MEMD.

In some embodiments and as outlined herein below in more detail, a charging arrangement may in some embodiments, act as a chemical sensor. For example, a negatively charged first conductive element 210 may attract positively charged ions and/or molecules.

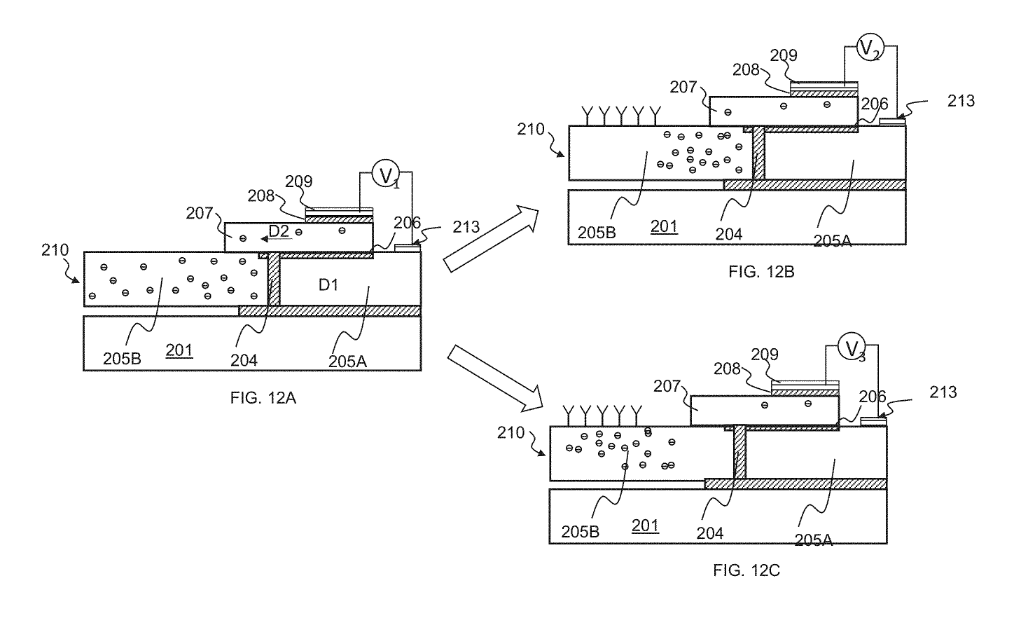

Reference is made to FIGS. 11A and 11B, which describe an MEMD in sensing mode, in which the first and second conductive elements may be fabricated one next to each other in alternating arrangement. Both conductive elements may be fixed or partly fixed to a common substrate but electrically isolated from it. After charging a first conductive element 210 of a charging arrangement 310, such as using FGCD, the surface of conductive element 210 may attract ions or molecules 311 as shown in FIG. 12B. The adherence of molecules redistributes at least some of the charges in conductive element 220. The charge redistribution may be sensed by employing an electrical circuit connected to pad 226. For example, as schematically shown in FIG. 11B, a change in measured voltage from V1 to V2 between the second conductive element and the reference potential may be indicative of molecule and/or ion adherence to conductive element 210. In another embodiment, a change in measured electrical current flowing from pad 226 to the reference potential may be indicative of a value of a parameter relating to a change in an environmental condition (e.g., adherence of ions and/or molecules). In some embodiments, a sensing MEMD may be employed for attracting, e.g., in a controllable manner, molecules and/or ions.

In some embodiments, the surface of the first conductive element may be modified such that only specific molecules may adhere to it (e.g., chlorine molecule) in which case the sensing MEMD may be employed to sense the presence of a specific molecule in the environment. Reference is made to FIGS. 12A and 12B. In a similar way to the chemical sensor described in FIG. 11, a conductive element can be charged for attracting, e.g., in a controllable manner, molecules and/or ions. Attracted molecules may redistribute the charge within the conductive element which in turn may cause a voltage drop or increase, depending on whether on the type or charge sign of charged adhering to the surface. As shown in FIGS. 12B and 12C depending on the surface treatment made to the conductive element, negatively charged molecules or ions may be attracted to the element (FIG. 12B) or positively charged molecules or ions may be attracted to it (FIG. 12C). When negatively charged molecules or ions adhere to the conductive element, the voltage measured on the charging gate increases, as the concentration of electron between the charging gate and the floating gate increases. When positively charged molecules or ions adhere to the conductive element the electron they attract electron away from the gate area and therefore the concentration of electrons between the charging gate and the floating gate decreases and the voltage drops.

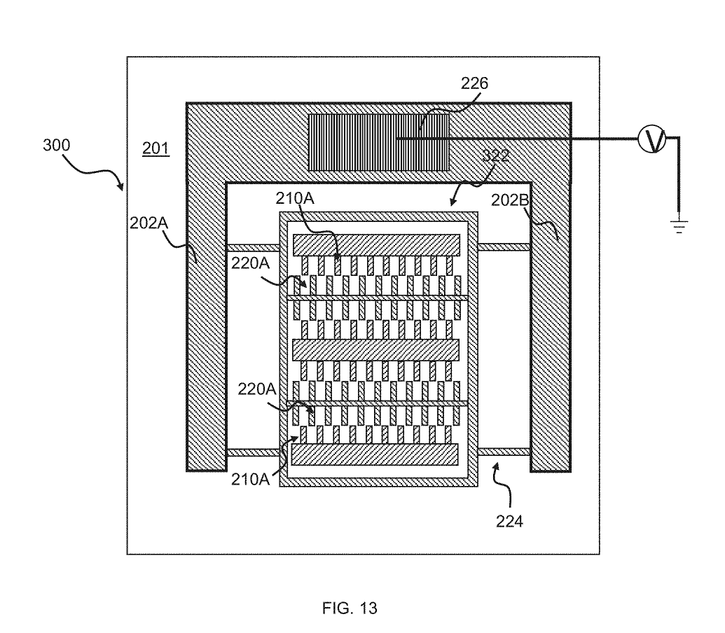

Additional reference is made to FIG. 13 that describes a displacement sensor. FIG. 13 is similar to embodiment shown in FIG. 8A but is not limited to it. The only difference is the measuring circuit connected to the second conductive element. In FIG. 8B the device is connected to a rectifying circuit while in FIG. 13 the device may be connected to a circuit that measures the voltage change between the pad 226 and the reference potential. The change in the voltage may be results from relative movement between first conductive elements 210A-210D and second conductive elements 220A-220D. Such relative movement may for example be the results of vibration, acceleration or other forces such as Coriolis forces acting on the MEMD. In the embodiment of FIG. 13 the device is an acceleration displacement sensor.

It is noted that all of the embodiment discussed above in reference to energy harvesting may be applied to acceleration sensor either by using the same rectifying circuit or by using a different electrical circuit, such as the circuit shown in FIG. 13, to translate the relative displacement between conductive elements 210 and 220 into an electrical signal. It also clear that an electrical amplifier may be used to amplify the signal in a sensing configuration of the embodiments above.

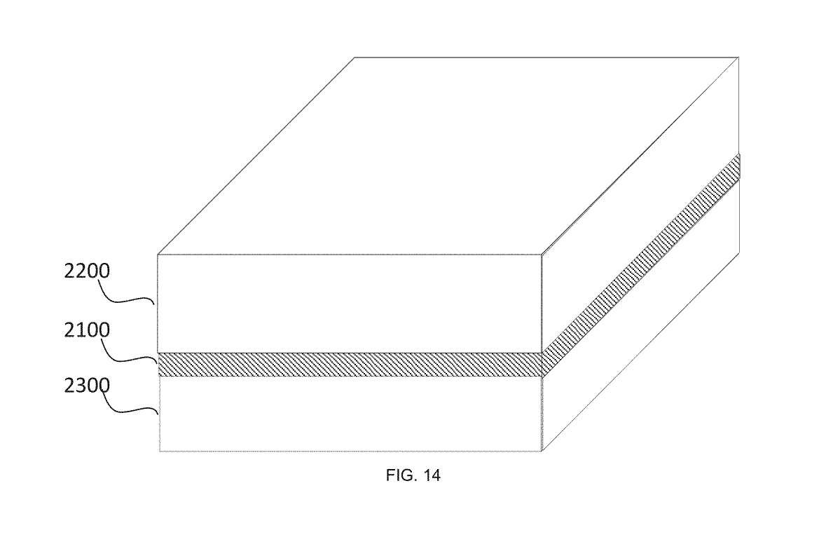

Reference is made to FIG. 14. A method for manufacturing a charging arrangement may include providing a SOI wafer 2000 comprising a Between Oxide Layer (BOX) 2100 interposed between an upper silicon layer called the device layer 2200 and lower Silicon carrier wafer 2300.

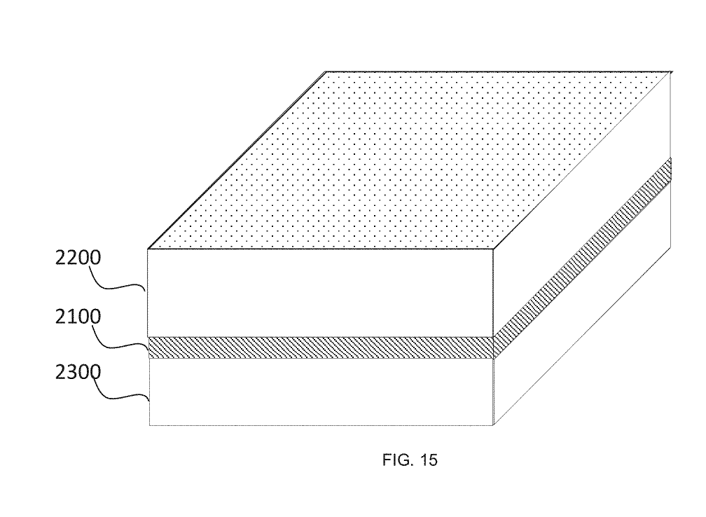

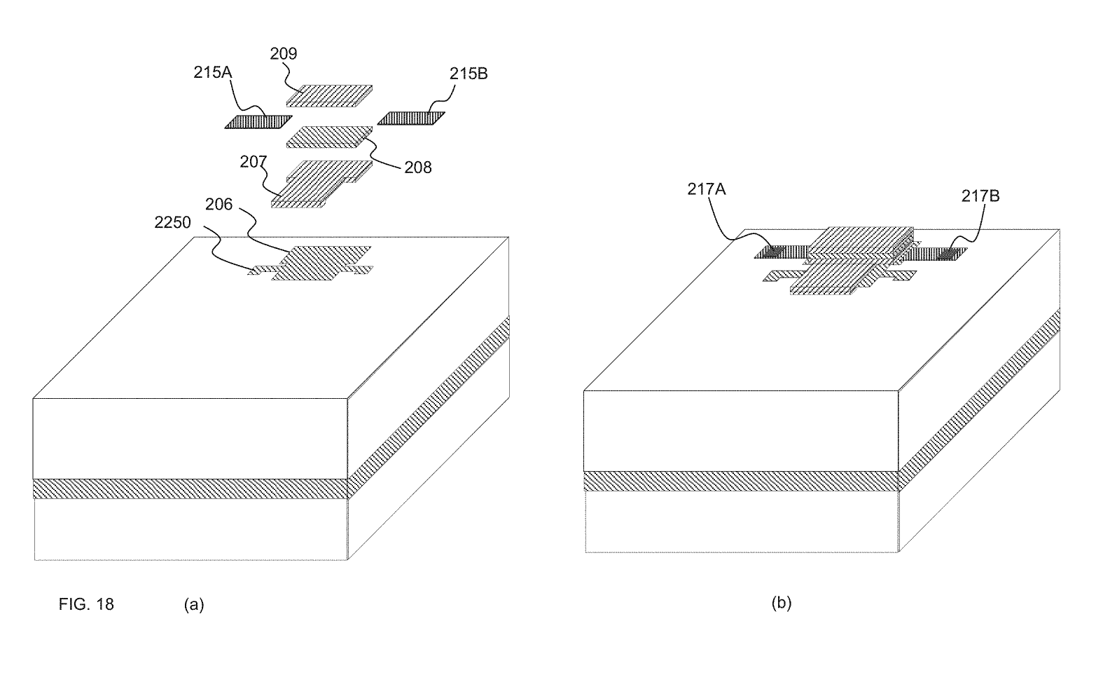

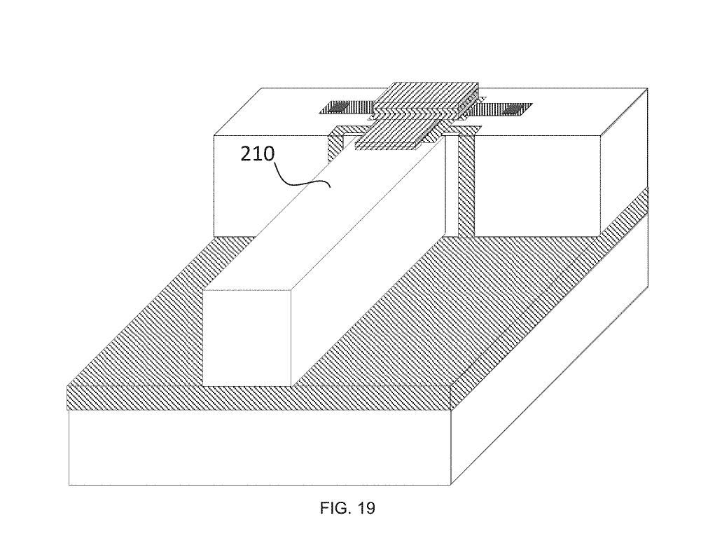

As shown schematically in FIG. 15, the method may then include providing, e.g., aSi₃N₄ coating for preventing oxidation underneath it, as in FIG. 18.

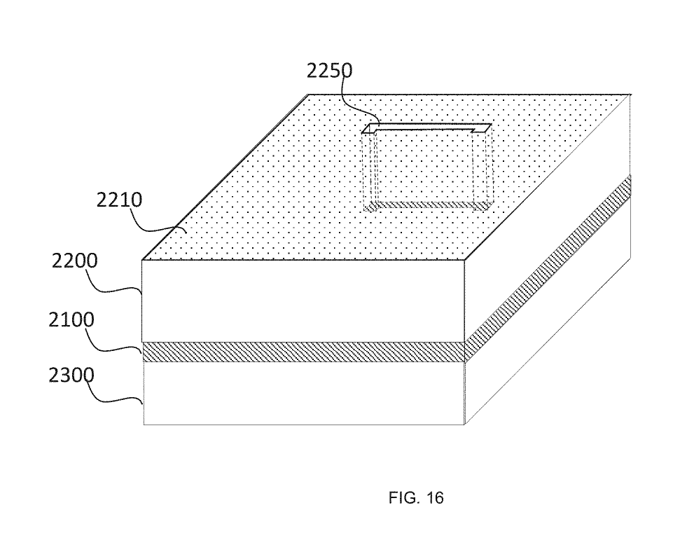

As shown schematically in FIG. 16, the method may further include forming a U-shaped trench 2250 extending in wafer 2000 all across device layer 2200 down to the upper side of the oxide layer 2100, by employing for example photolithography for pattern transfer, which may be followed by, e.g., Deep Reactive Ion Etching (DRIE) of the device layer down to the oxide layer 2100.

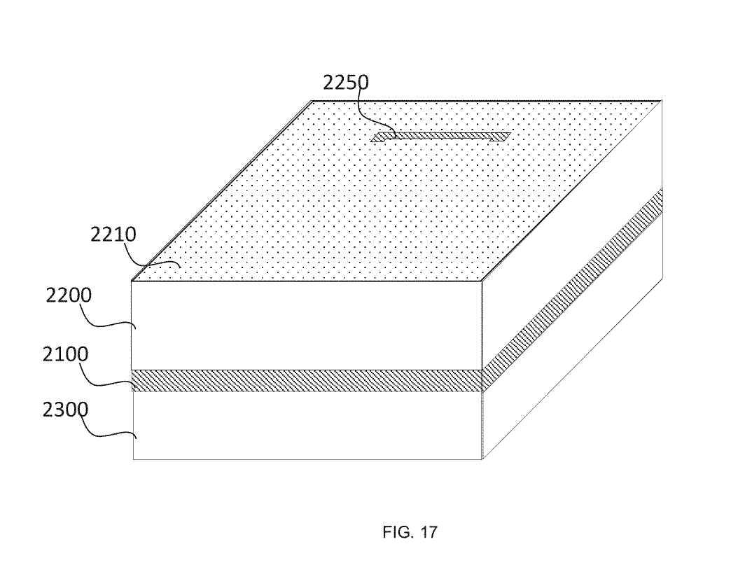

As shown schematically in FIG. 17, the method may include performing thermal oxidation of the wafer such that the inner surface of U-shaped trench 2250 is filled with oxide. It is noted that other filling materials may be used.

As shown schematically in FIG. 18, the method may further include employing a manufacturing process for obtaining a FGCD that is integrated with first conductive element 210. FIG. 18 shows in (a) a breakdown of the process. The integrated FGCD process may include patterning the Si3N4 layer in FIG. 15 to expose Silicon and an oxidation step that oxidizes the exposed Silicon to form the tunnel oxide 206 such that oxidation extends beyond the insulating barrier 2250. Next the floating gate 207 is deposited and patterned such that it extends beyond the tunnel oxide 206 and makes an ohmic contact with the silicon beyond the tunnel oxide.

The use of insulating barrier 2250, and the specific patterning the tunnel oxide and the floating gate are unique to the proposed process and are not common in state of the art FGCD technology. Source 215A and Drain 215B steps may follow by doping the areas on the two sides of the floating gate. An insulating layer 208 and a charging gate 209 are deposited and patterned to complete the FGCD step.

The method may include deposition and patterning of pads 217A and 217B as shown in FIG. 18 (b). The pad metallization comes last in the FGCD process.

As shown schematically in FIG. 19, the method may include employing photolithography, image transfer and DRIE down to the BOX such to obtain first conductive member 210.

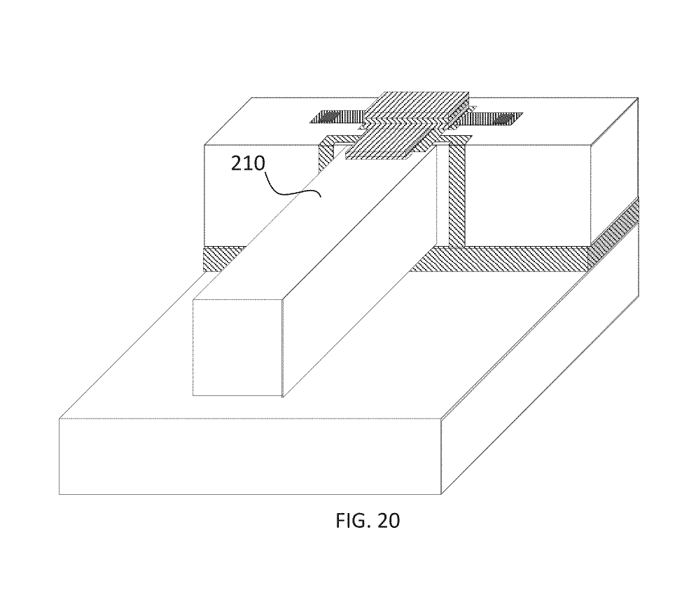

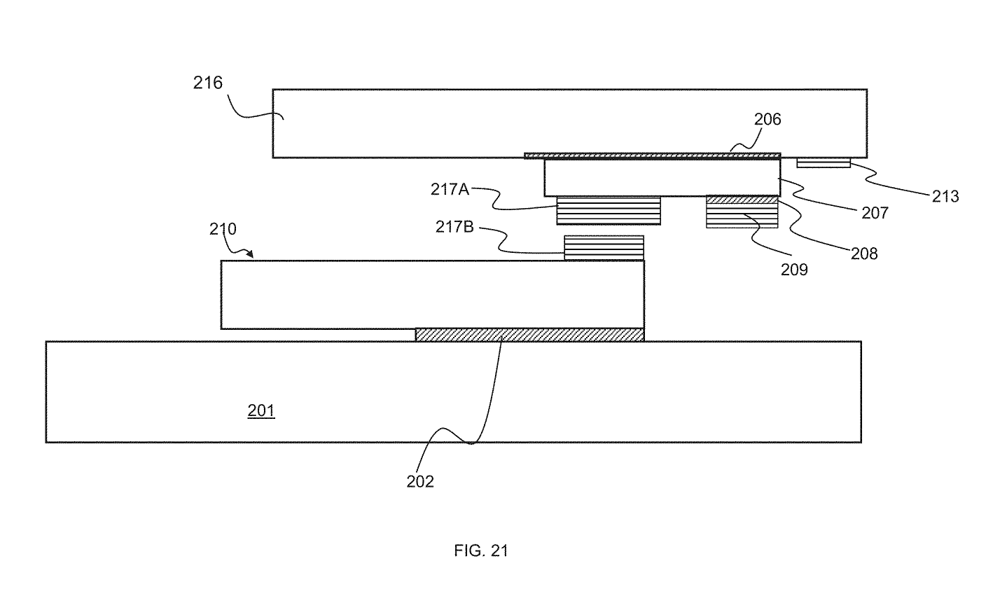

As shown schematically in FIG. 20, the method may then include removal of the BOX.

Reference is now made to FIG. 21, which describes another example of a fabrication process of the MEMD. FIG. 21 is a side view showing one first fixed conductive element 210 fabricated in one wafer such as discussed in different embodiments. One floating gate charging device is fabricated on a second wafer 216. When the two wafers are bonded to each other, a contact such as eutectic contact, is formed between pads 217A and 217B, forming an electrical contact between the floating gate 207 and element 210.

Other processes may be used including, for example, a process that includes an etch from the back side of substrate 201, in selective places, all the way to oxide 202, followed by an etch of this oxide to release suspended elements 220. It is also noted that instead of using SOI wafers, Silicon on Glass (SOG) wafers may be used.

It is further noted that the microfabrication processes described above are just examples of many possible process flows.

In the discussion, unless otherwise stated, adjectives such as “substantially” and “about” that modify a condition or relationship characteristic of a feature or features of an embodiment of the invention, are to be understood to mean that the condition or characteristic is defined to within tolerances that are acceptable for operation of the embodiment for an application for which it is intended.

Positional terms such as “upper”, “lower” “right”, “left”, “bottom”, “below”, “lowered”, “low”, “top”, “above”, “elevated”, “high”, “vertical” and “horizontal” as well as grammatical variations thereof as may be used herein do not necessarily indicate that, for example, a “bottom” component is below a “top” component, or that a component that is “below” is indeed “below” another component or that a component that is “above” is indeed “above” another component as such directions, components or both may be flipped, rotated, moved in space, placed in a diagonal orientation or position, placed horizontally or vertically, or similarly modified. Accordingly, it will be appreciated that the terms “bottom”, “below”, “top” and “above” may be used herein for exemplary purposes only, to illustrate the relative positioning or placement of certain components, to indicate a first and a second component or to do both. Further, directional terms such as “upwards” and “downwards” as used herein may indicate relative movement.

“Coupled with” means “coupled with directly or indirectly”.

It is important to note that the method is not limited to those diagrams or to the corresponding descriptions. For example, the method may include additional or even fewer processes or operations in comparison to what is described herein. In addition, embodiments of the method are not necessarily limited to the chronological order as illustrated and described herein.

It should be understood that where the claims or specification refer to “a” or “an” element, such reference is not to be construed as there being only one of that element.

In the description and claims of the present application, each of the verbs, “comprise” “include” and “have”, and conjugates thereof, are used to indicate that the object or objects of the verb are not necessarily a complete listing of components, elements or parts of the subject or subjects of the verb.

Unless otherwise stated, the use of the expression “and/or” between the last two elements of a list of options for selection indicates that a selection of one or more of the listed options is appropriate and may be made.

It is noted that the term “perspective view” as used herein may also refer to an “isometric view”.

It is appreciated that certain features of the invention, which are, for clarity, described in the context of separate embodiments or example, may also be provided in combination in a single embodiment. Conversely, various features of the invention, which are, for brevity, described in the context of a single embodiment, may also be provided separately or in any suitable sub-combination or as suitable in any other described embodiment of the invention. Certain features described in the context of various embodiments are not to be considered essential features of those embodiments, unless the embodiment is inoperative without those elements.

All references mentioned in this specification are herein incorporated in their entirety by reference into the specification, to the same extent as if each individual patent was specifically and individually indicated to be incorporated herein by reference. In addition, citation or identification of any reference in this application shall not be construed as an admission that such reference is available as prior art to the present application.

1-24. (canceled)

25: A micro-electromechanical device (MEMD) for sensing and for harvesting electrical energy, comprising:
a) at least one first conductive element mounted on a first support, wherein the at least one first conductive element is chargeable with electrons; and
b) at least one second conductive element mounted on a second support such that the first and second supports are electrically isolated from each other.
c) an electronic circuit operably coupled with either said at least one first conductive element or said at least one second conductive element.
Such that the said at least one first conductive element or said at least one second conductive element is inertia-mounted such that when subject to mechanical force a relative movement is induced between the said at least one first conductive element and the said at least one second conductive element such that the charge that is displaced as a result of the said relative movement, is read by the said an electric circuit.

26: The MEMD of claim 25, further comprising a floating gate charging device (FGCD) having a tunnel oxide, the floating gate charging device used for charging the said at least one first conductive element selectively and controllably by tunneling electrons through the tunnel oxide into the at least one first conductive element, the FGCD is electrically isolated from the said at least second conductive element.

27: The MEMD of claim 26, wherein the FGCD further comprises a source and drain for tunneling hot electrons to a floating gate of the FGCD responsive to applying a voltage between the source and the drain.

28: The MEMD of claim 26, wherein the FGCD has a charging polarity and a discharging polarity, wherein the charging polarity is used to charge the at least one first conductive element and the discharging polarity is used to drain the electrons out of the at least one first conductive element.

29: The MEMD of claim 28, wherein the charging or discharging includes a plurality of charging or discharging cycles such that each charging or discharging cycle may take less than one second.

30: The MEMD of claim 25 wherein the induced charge displacement is rectified, and/or up or down converted for the charging of a battery or the powering of an electrical device.

31: The MEMD of claim 26 wherein the induced charge displacement is rectified, and/or up or down converted for the charging of a battery or the powering of an electrical device.

32: The MEMD of claim 25 further include an electrical circuit to sense the charging level of the said at least one first conductive element, once charged, such that when the charge level decrease below a predetermined value, a recharging of the said one first conductive element takes place.

33: The MEMD of claim 32 wherein the power for the said recharging of the said one first element comes either from a battery or directly from the rectified power that is converted from the movement.

34: The MEMD of claim 25, wherein the induced charge displacement is measured for obtaining a value indicative of a displacement of the MEMD.

35: The MEMD of claim 26, wherein the induced charge displacement is measured for obtaining a value indicative of a displacement of the MEMD.

36: The MEMD of claim 25, wherein the at least one first conductive element is made from semiconductor material that is highly doped with Donors atoms to form a N type semiconductor.

37: The MEMD of claim 26, wherein the at least one first conductive element is made from semiconductor material that is highly doped with Donors atoms to form a N type semiconductor.

38: The MEMD of claim 25, wherein the at least one first conductive element is made from semiconductor material that is highly doped with Acceptors atoms to form a P type semiconductor such that the charging electrons recombine with holes such that the said one first conductive element is charged by negatively charged Acceptor ions.

39: A chemical sensor comprising a MEMD according to claim 25, wherein a charged said one first conductive element is used for sensing the presence of charged molecules and/or ions by redistributing the charge in the second conductive element upon adhering of such molecules or ions to the at least one first conductive element.

40: The chemical sensor of claim 39, wherein the at least one first conductive element comprises a chemically modified surface to attract a specific type of molecules and/or ions, such that electrons are redistributed in the second conductive element upon adhering of such molecules or ions to the first conductive element.

41: A chemical sensor comprising a FGCD and at least one first conductive element having a surface, wherein the at least one first conductive element is chargeable through the FGCD to create a potential difference between a charging gate of the FGCD and a reference potential and such that molecules and/or ions can adhere to the surface, wherein the adhering causes the electrons to redistribute in the at least one first conductive element, modifying the potential difference between a charging gate of the FGCD and the reference potential.

42: A chemical sensor comprising a FGCD and at least one first conductive element having a surface that is chemically modified to attract a specific type of molecules and/or ions, wherein the at least one first conductive element is chargeable through the FGCD to create a potential difference between a charging gate of the FGCD and a reference potential and such that when said specific type of molecules and/or ions adhere to the surface, wherein the electrons in the at least one first conductive element redistribute and modify the potential difference between a charging gate of the FGCD and the reference potential.

43: A method of fabricating a MEMD of claim 25 wherein the at least one first conductive element and the at least one second conductive element are fabricated from the same semiconductor wafer.

44: A method of fabricating a MEMD of claim 26 wherein the said FGCD, the at least one first conductive element, the at least one second conductive element are fabricated from the same semiconductor.

45: A method of fabricating the chemical sensor according to claim 41, wherein the at least one first conductive element and the FGCD are fabricated from the same semiconductor wafer.

46: A method of fabricating the chemical sensor according to claim 42, wherein the at least one first conductive element and the FGCD are fabricated from a single semiconductor wafer.
